(19) United States
(12) Patent Application Publication
(10) Pub. No.: US 2006/0186509 A1
(43) Pub. Date: Aug. 24, 2006

(54) Shallow trench isolation structure with active edge isolation

(75) Inventor: Bradley J. Larsen, Mound, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc., Morristown, NJ (US)

(21) Appl. No.: 11/064,556

(22) Filed: Feb. 24, 2005

(51) Int. Cl. H01L 29/00; H01L 21/76

(52) U.S. Cl. 257/506; 438/435; 257/510; 438/437

(57) ABSTRACT

A method of fabricating a shallow trench isolation (STI) structure with active edge isolation and increased radiation hardening is presented. The invention comprises forming a pad oxide layer on a substrate. Then a masking layer is formed on the pad oxide and is patterned to define the STI structure trench and spacer locations. A conformal layer of oxide is deposited and is formed into oxide spacers which extend over the active edge of the substrate. The STI structure trench is then etched and a liner oxide is formed on the walls of the trench. The trench is then filled with a dielectric material to form a central oxide region. The central oxide region and oxide spacers are then etched to a desired height and planarized. Finally, the masking layer and portions of the pad oxide layer are then removed.

### FIELD

The present invention relates to the field of semiconductor device processing and, more especially, to methods for creating shallow trench isolation structures with improved radiation hardening properties.

### BACKGROUND

Semiconductor circuits are generally processed with multiple and various devices on a single substrate. As processing techniques have improved and allowed device dimensions to shrink, the proximity of devices has also increased substantially. As a result, the electrical isolation of each device from its neighbors has also been reduced. The lack of isolation between neighboring devices can cause a variety of performance-degrading problems including increased leakage current, latch-up of transitional devices, decreased noise margins and thresholds, and increased susceptibility to electrical noise and radiation-induced errors.

In order to increase the electrical isolation of individual devices on a single substrate while still maintaining an effective use of semiconductor area, shallow trench isolation (STI) has frequently been utilized. In this method, shallow vertical trenches are created between devices and are then filled with a dielectric material, such as silicon dioxide or a derivative. The trenches are narrow enough to avoid excessive consumption of semiconductor area; however, the trenches extend deep enough into the substrate to prevent carrier migration and charge sharing between devices. In the case of silicon on insulator (SOI) substrates, the trenches generally extend all the way to the insulating layer below the silicon, giving each device increased electrical isolation from nearby device elements.

Despite the improved isolation provided by STI processes, the boundary created by the trench at the intersection of the active semiconductor, gate oxide, and polysilicon gate interfaces can cause additional undesired effects. At the top corner of the active semiconductor, the degree to which the gate oxide wraps around this edge can lead to problems associated with gate oxide integrity, subthreshold voltage characteristic stability, and radiation hardness. More specifically, increased wraparound leads to strained gate oxides, subthreshold voltage leakage, and increased susceptibility to radiation ionization effects and single-event error effects.

Aside from the boundary at the top corner of the semiconductor, the interface between the active semiconductor and the trench dielectric also affects the radiation hardness of devices. Large areas of dielectric material are especially susceptible to ionization damage caused by radiation. This type of damage results from highly energized radiated particles bombarding the material and creating electron hole pairs. These pairs generally recombine without permanent damage in semiconductor materials; however, in dielectric materials and in the presence of an applied voltage, the electrons are swept out of the material while the relatively immobile and positively charged holes are left behind. In isolation trenches, these resulting net charges build up at the oxide interface and can cause threshold voltage degradation when the interface is located at a device channel.

The problem arising at the active edges of STI trenches has previously been solved by changing the geometry of the edge itself. Rounding the top corner of the semiconductor edge allows the thin gate oxide to wrap around a more gradual transitioning geometry. This has the effect of lowering the electric fields of the interface and also helps to avoid the formation of parasitic corner transistors. However, in order to perform corner rounding, the active isolation edge must physically be exposed at some point during the fabrication process. As a result, subsequent localized oxidation at this corner results in a high stress film that is more susceptible to radiation effects. Furthermore, the corner rounding technique does not help to mitigate the effects of radiation ionization damage in the trench dielectric.

It would be desirable to develop an STI process that addresses the problems associated with the sharp geometry of the upper corner of the active semiconductor as well as provides increased immunity to radiation effects resulting from ionization damage to the trench dielectric region. Furthermore, it is necessary that the process maintain compatibility with current semiconductor device manufacturing processes.

### BRIEF DESCRIPTION OF THE DRAWINGS

Presently preferred embodiments are described below in conjunction with the drawing figures, wherein like reference numerals refer to like elements in the various figures, and wherein:

FIG. 1 is a cross-sectional view of an STI structure fabricated on an SOI substrate, according to one embodiment;

FIGS. 2-9 are cross-sectional views of the STI device structure shown in FIG. 1 during various stages of fabrication, according to one embodiment; and

FIG. 10 is a process flow diagram illustrating a method for forming the SOI device structure shown in FIG. 1, according to one embodiment.

### DETAILED DESCRIPTION

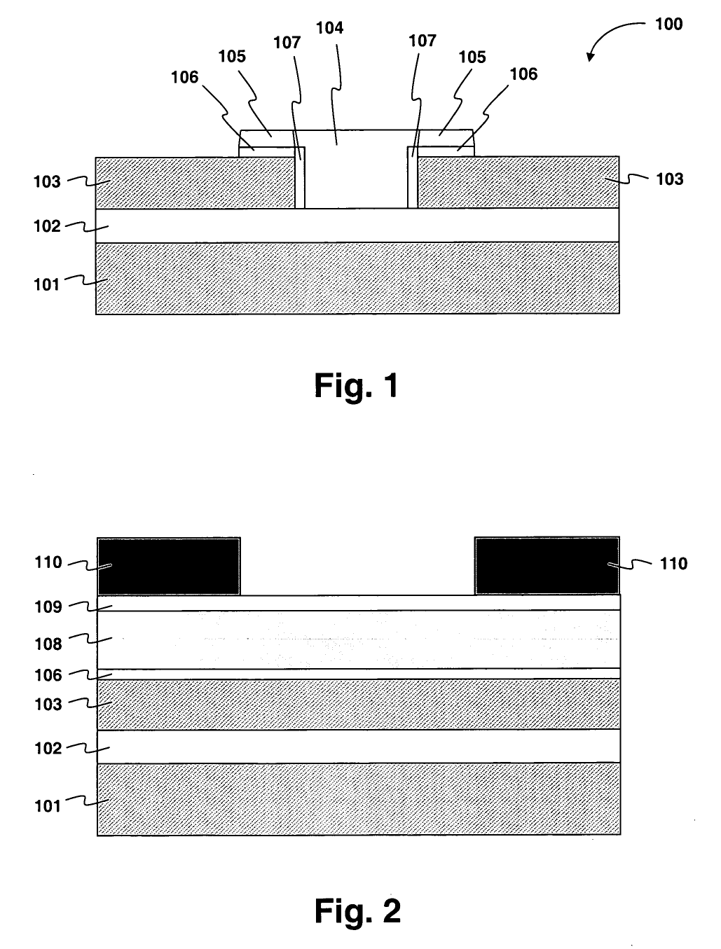

FIG. 1 shows an embodiment of a shallow trench isolation (STI) structure 100 formed on SOI using the radiation hardening process as described herein. The STI structure consists of four main oxide regions that together provide isolation between adjacent active silicon areas and also isolate gate layers from active silicon areas.

The central field oxide region 104 provides a structural isolation barrier between adjacent active silicon areas 103 and may be formed using a high-density plasma chemical vapor deposition (HDPCVD) process with SiH₄ and O₂ as the reactive gases. The oxide spacer regions 105 may be formed using a plasma-enhanced chemical vapor deposition (PECVD) or HDPCVD process, or a low temperature oxidation (LTO) growth. The oxide spacer region 105 act as electrical barriers between the active silicon areas 103 and any superior layers that may subsequently be formed. The pad oxide regions 106 and liner oxide region 107 may consist of thermally grown oxide, and both regions offer increased electrical isolation. The pad oxide region 106 helps to relieve stress between the spacer oxide region 105 and the active silicon area 103, while the liner oxide region helps to relieve mechanical stress between the central field oxide region 104 and the active silicon area 103. Because regions that are high in mechanical stress are more radiation sensitive, the liner oxide regions also serve to increase the radiation hardness of the structure.

The side lobes formed by the spacer oxide regions 105 and the liner oxide regions 106 help mitigate the high electrical field concentrations found at active region corners and also provide an oxide barrier to combat radiation effects. Because ionization effects due to radiation bombardment are most pronounced in dielectric isolation regions, and notably those composed of silicon dioxide, the side lobes provide a buffer between the channel regions of the MOS devices and the potentially ionized shallow trench isolation structures.

FIG. 2 shows the STI structure 100 in the early stages of processing on a SOI substrate according to an exemplary embodiment. A silicon base substrate 101 may be covered with an isolation oxide layer 102. An active silicon layer 103 may be formed on top of the buried oxide layer 102. The active silicon layer 103 may be between 200 and 3000 Angstroms thick and may have a crystal orientation of <100>. Alternatively, another semiconductor substrate may be utilized for the fabrication of the STI structure 100 instead of the SOI layer stack.

On top of the active silicon layer 103 a pad oxide layer 106 is formed. The pad oxide layer 106 may be 20 to 300 Angstroms thick and may be thermally grown. A bi-layer masking layer is then formed on top of the pad oxide layer 106. The bottom layer of the masking layer may consist of a nitride mask layer 108 that can be deposited on the pad oxide layer 106 using a PECVD, HDPCVD, low-pressure chemical vapor deposition (LPCVD), or related process to a thickness between 400 and 2500 Angstroms. The top layer of the masking layer may consist of an oxide hard mask layer 109 having been deposited on top of the nitride mask layer 108 using a PECVD, HDPCVD, or low temperature oxide (LTO) process to a thickness between 200 and 2500 Angstroms. Alternatively, the masking layer may consist of only a single layer of nitride, oxide, or other suitable masking material.

A layer of patterned photoresist 110 can be formed on top of the masking layer to be used as a mask for patterning the masking layer. This layer may also consist of an electron-sensitive resist, or another patternable film with a propensity for resistance to dry etch processes.

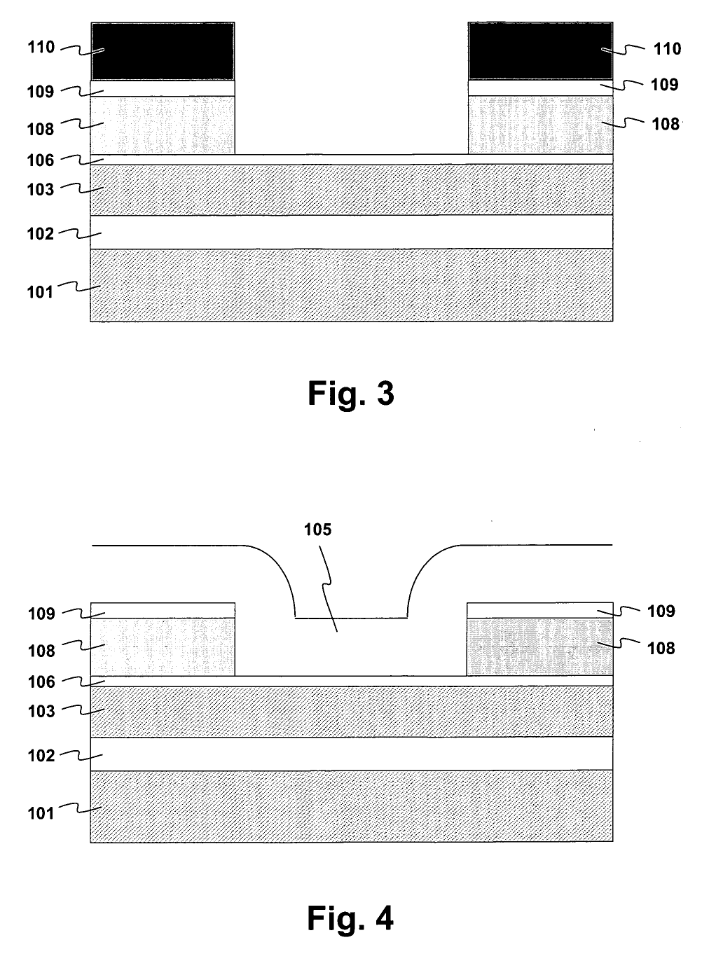

FIG. 3 shows the continued processing of the STI structure 100 according to the exemplary embodiment. The masking layer is etched using the photoresist 110 as a mask, thereby creating gaps in the masking layer that can be used to define the STI trench. Etching the masking layer may be performed using an ICP-RIE system with chlorine based gasses. Alternatively, any dry plasma etching methods may be utilized to selectively etch the masking layer.

FIG. 4 shows the continued processing of the STI structure 100 according to the exemplary embodiment. The patterned resist mask 110 has been removed and a conformal oxide spacer layer 105 has been deposited on top of the sample. This oxide spacer layer 105 can be deposited using a PECVD process and may be 500 to 3000 Angstroms in thickness. Alternatively, this layer can be deposited using an HDPCVD or LTO process.

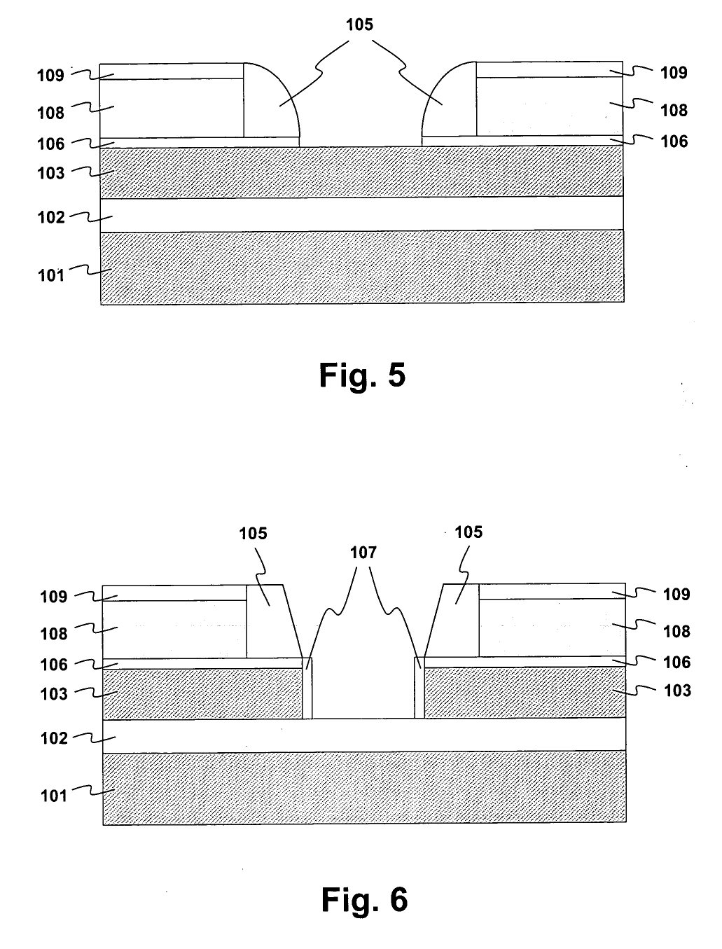

FIG. 5 shows the continued processing of the STI structure 100 according to the exemplary embodiment. The deposited spacer oxide layer 105 has been anisotropically etched to a sufficient depth to remove the oxide hard mask layer 109 and expose the active silicon layer 103 of the SOI substrate. This etching may be performed using a dry etch process, such as an ICP-RIE process with chlorine- or fluorine-based gasses; however other anisotropic etching processes may be utilized as well. Because of the conformal nature of the oxide spacer layer 105 deposition, the portions of the oxide spacer layer nearest the sidewalls of the masking layer gap exhibit a greater vertical thickness than other portions. As a result, the directional etch first removes the portions of the spacer oxide covering the masking layer and those portions located in the center of the masking layer gap, due to their relatively small thickness; however, the relatively thick portions of the oxide spacer nearest the sidewalls of the masking layer are etched less and survive the etching process.

FIG. 6 shows the continued processing of the STI structure 100 according to the exemplary embodiment. Portions of the active silicon layer 103 are selectively etched with the oxide hard mask 109 and spacer oxide layer 105 acting as an etch mask. The etching may be performed using a dry etch process, such as an ICP-RIE process with chlorine- or fluorine-based gasses; however other selective etching processes may be utilized as well. This etching process defines the STI structure trench in the active silicon layer.

A liner oxide 107 is subsequently formed on the sidewalls of the trench created by the etching process. The liner oxide 107 may be thermally grown using a conventional thermal furnace or rapid thermal processing (RTP) system. The thickness of the liner oxide 107 may be between 50 and 400 Angstroms.

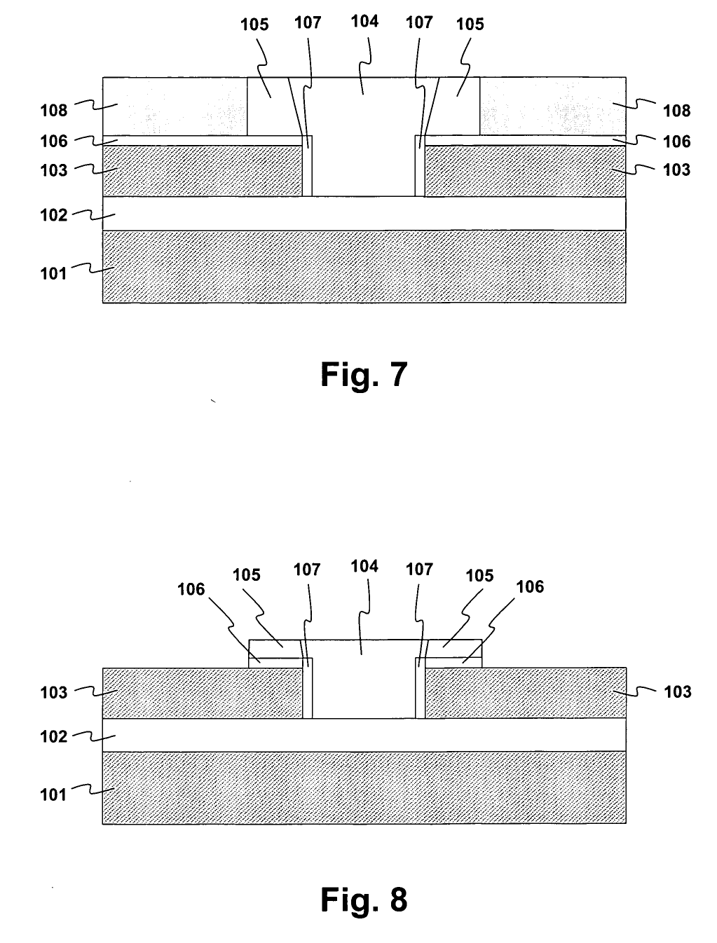

FIG. 7 shows the continued processing of the STI structure 100 according to the exemplary embodiment. Field oxide 104 is deposited into the oxide-lined trench. The field oxide 104 may be deposited using a chemical vapor deposition (CVD) method. Specifically, a HDPCVD process with SiH₄ as the base gas may be used in order to insure better step coverage. However, other oxide deposition methods which display sufficient step coverage may also be utilized. The amount of oxide deposited is generally enough to completely fill the trench and ranges from 1000 to 7000 Angstroms in thickness.

Following field oxide deposition the sample can be planarized to create a smooth and even surface. This planarization process also exposes the nitride mask layer 108. Planarization can be accomplished through a chemical mechanical polishing (CMP) process with a nitride selectivity ranging from 3:1 to 1000:1.

FIG. 8 shows the continued processing of the STI structure 100 according to the exemplary embodiment. An oxide etch is first performed to set the height of the STI structure 100. A solution of dilute HF (DHF) may be used to etch 50 to 400 Angstroms into the field oxide 104 and spacer oxide 105 regions. Alternatively, a buffered oxide etch (BOE) solution may be used as the etchant. Performing an oxide etch also helps to remove any residue from the top of the nitride mask layer 108 and prepare the substrate for a nitride etch process.

Following the oxide etch the nitride mask layer 108 can be removed. The nitride can be etched using a solution of hot phosphoric acid. Alternatively, other nitride strip techniques exist that are known to those experienced in the art. Selectively removing the nitride mask layer 108 via this process exposes the pad oxide layer 106 for subsequent processing.

The exposed pad oxide layer 106 can be etched completely using a DHF solution. Alternatively, a BOE solution may be used to remove the pad oxide. This etch process exposes the active silicon layer 103 for subsequent processing.

It is also possible to combine the three separate etches of the field oxide 104 and spacer oxide 105, nitride layer mask 108, and pad oxide layer 106 into one nitride etch and one oxide etch, where the latter precedes the former. In this embodiment, the nitride mask layer 108 is completely removed; then the field oxide 104 and spacer oxide 105 heights are set with the same etch process used to completely remove the pad oxide layer 106.

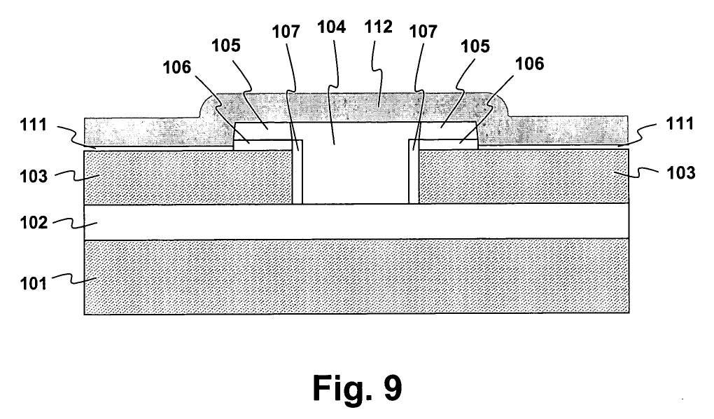

FIG. 9 shows the continued processing of the STI structure 100 according to the exemplary embodiment. A gate oxide layer 111 may be formed on exposed active silicon areas 103. This gate oxide layer 111 can be thermally grown in a conventional thermal furnace to a thickness between 10 and 200 Angstroms. Alternatively, an RTP process may be used to grow the gate oxide.

After the gate oxide has been formed, a polysilicon or amorphous silicon gate may be formed on top of the gate oxide. A polysilicon gate can be deposited using an LPCVD process at a temperature between 250° C. and 800° C. The gate is generally between 500 and 3000 Angstroms thick, although the actual thickness of the gate may vary.

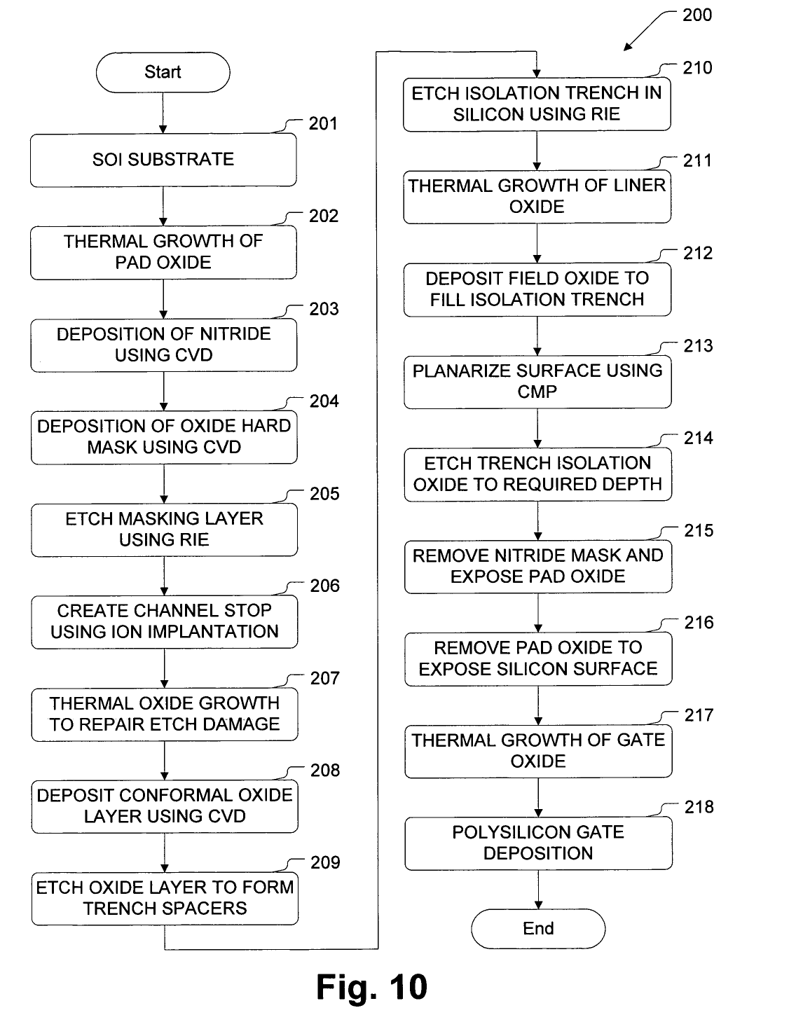

FIG. 10 provides a flow diagram illustrating a method 200 of forming the STI structure 100 according to an embodiment. This method 200 summarizes the processing steps described above with reference to FIG. 2 through FIG. 9. In addition, this method 200 includes additional processing steps according to an exemplary embodiment.

Following the mask layer etching 205 illustrated in FIG. 3 and prior to the spacer oxide deposition 208 illustrated in FIG. 4, two processing steps may be performed to increase the radiation hardness of the STI structure. The first step is the creation of a self-aligned channel stop using ion implantation 206 with the using the nitride mask layer 108, hard mask layer 109, and photoresist layer 110 as a mask. The channel stop should be implanted through the pad oxide layer 106 and into the active semiconductor substrate 103. The ion dose used for the channel stop may be about 1×10¹¹ to about 1×10¹⁴ ions/cm².

The second additional process illustrated in the flow diagram is a thermal oxidation 207. This step can occur after the creation of a channel stop and prior to the deposition of the conformal spacer oxide layer. Additionally, if a channel stop is not created, the thermal oxidation may sequentially follow the etching of the masking layer. The oxidation can be performed in a conventional thermal furnace or in an RTP system. The oxidation may be performed at a temperature of about 300 to about 1000° C., and may last about 10 seconds to 3 hours. The thermal oxidation aids in repairing any damage of the pad oxide layer 106 resulting from the masking layer etch or the channel stop ion implantation process.

Exemplary embodiments of the present invention have been illustrated and described. It should be noted that the figures are not drawn to scale and are approximations of an exemplary embodiment. For example, corners may be rounded in an exemplary embodiment, rather than straight as depicted. It will be understood, that variations in form and detail may be made to the invention without deviating from the spirit and scope of the invention, as defined by the following claims.

1. A shallow trench isolation structure on a semiconductor substrate comprising:
a central region having a lower portion extending into the semiconductor substrate and an upper portion rising above the semiconductor substrate;
chemical vapor deposited oxide spacers extending outward from the upper portion of the central region and projecting over the semiconductor substrate;
a liner region positioned between the semiconductor substrate and the lower portion of the central region; and
a pad region positioned between the semiconductor substrate and the oxide spacers.

2. The structure of claim 1 where the semiconductor substrate is silicon on insulator (SOI).

3. The structure of claim 1 where the central region comprises chemical vapor deposition (CVD) deposited oxide with a vertical thickness between about 1000 and about 7000 Angstroms.

4. The structure of claim 1 where the oxide spacers have a vertical thickness between about 100 and about 1000 Angstroms, and a horizontal width of about 500 to about 3000 Angstroms.

5. The structure of claim 1 where the liner region comprises thermally grown oxide with a thickness between about 50 and about 400 Angstroms.

6. The structure of claim 1 where the pad region comprises thermally grown oxide with a thickness between about 20 and about 300 Angstroms.

7-22. (canceled)
